(19) United States
(12) Patent Application Publication
(10) Pub. No.: US 2022/0359195 A1
(43) Pub. Date: Nov. 10, 2022

(54) METHODS FOR FORMING AN EPITAXIAL WAFER

(71) Applicant: GlobalWafers Co., Ltd., Hsinchu (TW)

(72) Inventors: Maria Porrini, Merano (IT); Pietro Valcozzena, Agordo (IT)

(21) Appl. No.: 17/712,859

(22) Filed: Apr. 4, 2022

Related U.S. Application Data
(60) Provisional application No. 63/184,424, filed on May 5, 2021.

(51) Int. Cl. H01L 21/02; H01L 21/203; H01L 21/205; C30B 25/20

(52) U.S. Cl. CPC H01L 21/02293; H01L 21/2033; H01L 21/2053; C30B 25/205; C30B 29/06

(57) ABSTRACT

Methods for preparing epitaxial wafers are disclosed. The methods may involve control of the (i) a growth velocity, v, and/or (ii) an axial temperature gradient, G, during the growth of an ingot segment such that v/G is less than a critical v/G. An epitaxial layer is deposited on a substrate sliced from the silicon ingot.

### CROSS-REFERENCE TO RELATED APPLICATION

This application claims the benefit of U.S. Provisional Patent Application No. 63/184,424, filed May 5, 2021, which is incorporated herein by reference it its entirety.

### FIELD OF THE DISCLOSURE

The field of the disclosure relates to methods for forming an epitaxial wafer and, in particular, methods that involve forming an epitaxial wafer having a relatively thick denuded zone in the substrate below the interface between the epitaxial layer and the substrate.

### BACKGROUND

Epitaxial wafers include a single crystal silicon substrate with an epitaxial layer deposited on the front surface of the substrate. Epitaxial wafers may be used to form electronic devices suitable for microelectronic (integrated circuits or power applications) or photovoltaic use.

Epitaxial wafers may have surface defects which degrade their performance. Heavily doped epitaxial wafers (e.g., p/p+) offer good protection against latch up, good slip resistance and good gettering properties due to enhanced metal solubility in heavily-doped silicon and internal gettering which is promoted by high boron concentration. Heavily doped boron substrates are prone to the formation of a high density of oxygen precipitates (BMD). Oxygen precipitates exacerbate dislocation and slip such as in power semiconductor devices which use deep trenches for isolation.

A need exists for heavily-doped epitaxial wafers that form a relatively thick denuded zone below the epitaxial layer during subsequent high temperature anneals.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

An aspect of the present disclosure is directed to a method for forming an epitaxial wafer comprising a substrate and an epitaxial layer disposed on the substrate. An initial charge of polycrystalline silicon is added to a crucible. The crucible comprising the initial charge of polycrystalline silicon is heated to cause a silicon melt to form in the crucible. Boron is added to the crucible to produce a doped silicon melt. A silicon seed crystal is contacted with the doped silicon melt. The silicon seed crystal is withdrawn to grow a single crystal silicon ingot. The ingot has a constant diameter portion. The constant diameter portion of the ingot has a boron concentration of at least about 2.8×10¹⁸ atoms/cm³. A growth velocity, v, and/or an axial temperature gradient, G, are controlled during the growth of a segment of the constant diameter portion of the ingot such that v/G is less than a critical v/G. A plurality of silicon substrates are sliced from the single crystal silicon ingot. A front surface of one of the plurality of silicon substrates is contacted with a silicon-containing gas. The silicon-containing gas decomposes to form an epitaxial silicon layer on the silicon substrate.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a cross-section of an ingot puller apparatus before silicon ingot growth;

FIG. 2 is a cross-section of the ingot puller apparatus of FIG. 1 during silicon ingot growth;

FIG. 3 are schematic cross-section views of a single crystal silicon ingot showing the axial trend in vacancy-rich and interstitial-rich regions for three boron doping levels (increasing from (a) to (c));

FIG. 4 is a cross-section of a silicon substrate sliced from the silicon ingot;

FIG. 5 is a cross-section of a silicon substrate having a denuded zone formed at the surface thereof;

FIG. 6 is a cross-section of an epitaxial silicon wafer having a denuded zone formed at the surface thereof; and

FIG. 7 is a graph showing the denuded zone depth as a function of Δ (i.e., v/G−(v/G)_{crit}) with black symbols having a resistivity greater than 20 mΩ*cm and open symbols having a resistivity less than 20 mΩ*cm.

Corresponding reference characters indicate corresponding parts throughout the drawings.

### DETAILED DESCRIPTION

Provisions of the present disclosure relate to methods for forming heavily-doped epitaxial wafers having a relatively deep denuded zone disposed below the epitaxial layer. In accordance with embodiments of the present disclosure, the ratio (v/G) of the growth velocity (v) and the axial temperature gradient (G) may be controlled during growth of a segment or all of the constant diameter portion of a single crystal silicon ingot to be less than a critical v/G for the given boron concentration of the substrate. An epitaxial layer is deposited on substrates sliced from such ingots and the resulting heavily-doped epitaxial wafer is capable of forming a relatively thick denuded zone during a subsequent high temperature anneal, such as during device fabrication.

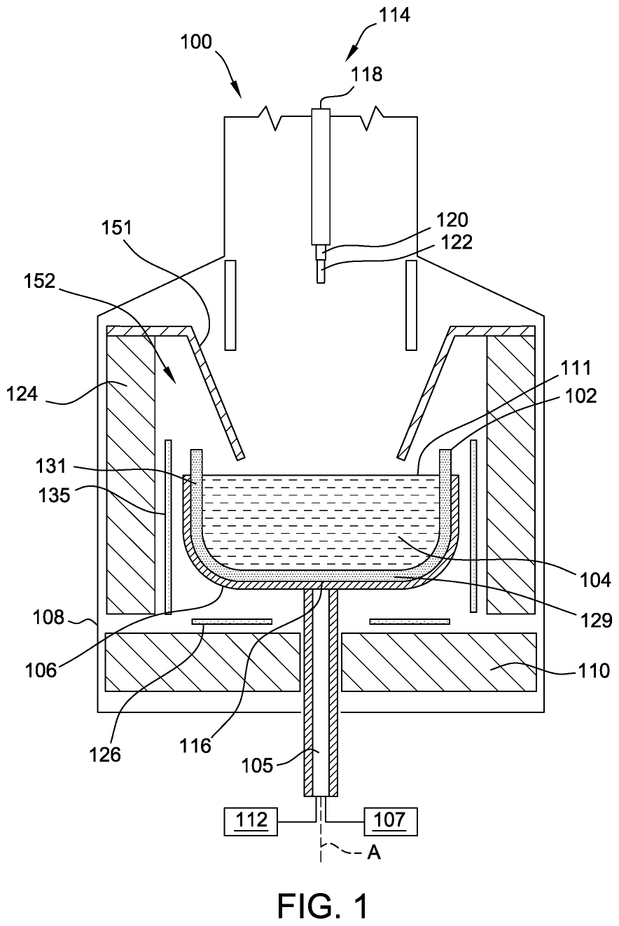

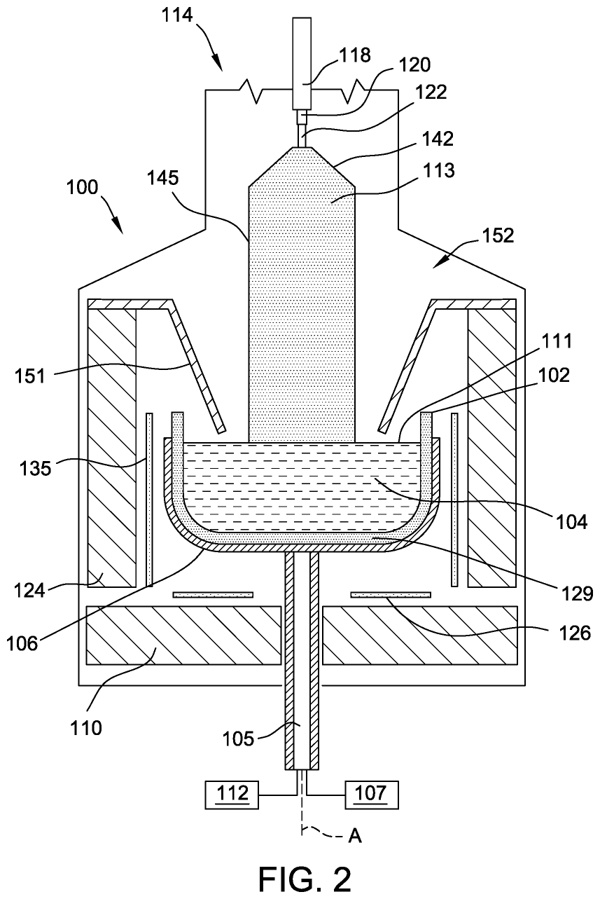

The methods of the present disclosure may generally be carried out in any ingot puller apparatus that is configured to pull a single crystal silicon ingot. An example ingot puller apparatus (or more simply “ingot puller”) is indicated generally at “100” in FIG. 1. The ingot puller apparatus 100 includes a crucible 102 for holding a melt 104 of semiconductor or solar-grade material, such as silicon, supported by a susceptor 106. The ingot puller apparatus 100 includes a crystal puller housing 108 that defines a growth chamber 152 for pulling a silicon ingot 113 (FIG. 2) from the melt 104 along a pull axis A.

The crucible 102 includes a floor 129 and a sidewall 131 that extends upward from the floor 129. The sidewall 131 is generally vertical. The floor 129 includes the curved portion of the crucible 102 that extends below the sidewall 131. Within the crucible 102 is a silicon melt 104 having a melt surface 111 (i.e., melt-ingot interface).

In some embodiments, the crucible 102 is layered. For example, the crucible 102 may be made of a quartz base layer and a synthetic quartz liner disposed on the quartz base layer.

The susceptor 106 is supported by a shaft 105. The susceptor 106, crucible 102, shaft 105 and ingot 113 (FIG. 2) have a common longitudinal axis A or “pull axis” A.

A pulling mechanism 114 is provided within the ingot puller apparatus 100 for growing and pulling an ingot 113 from the melt 104. Pulling mechanism 114 includes a pulling cable 118, a seed holder or chuck 120 coupled to one end of the pulling cable 118, and a silicon seed crystal 122 coupled to the seed holder or chuck 120 for initiating crystal growth. One end of the pulling cable 118 is connected to a pulley (not shown) or a drum (not shown), or any other suitable type of lifting mechanism, for example, a shaft, and the other end is connected to the chuck 120 that holds the seed crystal 122. In operation, the seed crystal 122 is lowered to contact the melt 104. The pulling mechanism 114 is operated to cause the seed crystal 122 to rise. This causes a single crystal ingot 113 (FIG. 2) to be withdrawn from the melt 104.

During heating and crystal pulling, a crucible drive unit 107 (e.g., a motor) rotates the crucible 102 and susceptor 106. A lift mechanism 112 raises and lowers the crucible 102 along the pull axis A during the growth process. For example, as shown in FIG. 1, the crucible 102 may be at a lowest position (near the bottom heater 126) in which an initial charge of solid-phase polycrystalline silicon previously added to the crucible 102 is melted. Crystal growth commences by contacting the melt 104 with the seed crystal 122 and lifting the seed crystal 122 by the pulling mechanism 114. As the ingot grows, the silicon melt 104 is consumed and the height of the melt in the crucible 102 decreases. The crucible 102 and susceptor 106 may be raised to maintain the melt surface 111 at or near the same position relative to the ingot puller apparatus 100 (FIG. 2).

A crystal drive unit (not shown) may also rotate the pulling cable 118 and ingot 113 (FIG. 2) in a direction opposite the direction in which the crucible drive unit 107 rotates the crucible 102 (e.g., counter-rotation). In embodiments using iso-rotation, the crystal drive unit may rotate the pulling cable 118 in the same direction in which crucible drive unit 107 rotates the crucible 102. In addition, the crystal drive unit raises and lowers the ingot 113 relative to the melt surface 111 as desired during the growth process.

The ingot puller apparatus 100 may include an inert gas system to introduce and withdraw an inert gas such as argon from the growth chamber 152. The ingot puller apparatus 100 may also include a dopant feed system (not shown) for introducing dopant into the melt 104.

According to the Czochralski single crystal growth process, a quantity of polycrystalline silicon, or polysilicon, is charged to the crucible 102. The initial semiconductor or solar-grade material that is introduced into the crucible is melted by heat provided from one or more heating elements to form a silicon melt in the crucible. The ingot puller apparatus 100 includes bottom insulation 110 and side insulation 124 to retain heat in the puller apparatus. In the illustrated embodiment, the ingot puller apparatus 100 includes a bottom heater 126 disposed below the crucible floor 129. The crucible 102 may be moved to be in relatively close proximity to the bottom heater 126 to melt the polycrystalline charged to the crucible 102.

To form the ingot, the seed crystal 122 is contacted with the surface 111 of the melt 104. The pulling mechanism 114 is operated to pull the seed crystal 122 from the melt 104. Referring now to FIG. 2, the ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone (not shown) in which the ingot tapers in diameter after the main body 145. When the diameter becomes small enough, the ingot 113 is then separated from the melt 104.

The ingot puller apparatus 100 includes a side heater 135 and a susceptor 106 that encircles the crucible 102 to maintain the temperature of the melt 104 during crystal growth. The side heater 135 is disposed radially outward to the crucible sidewall 131 as the crucible 102 travels up and down the pull axis A. The side heater 135 and bottom heater 126 may be any type of heater that allows the side heater 135 and bottom heater 126 to operate as described herein. In some embodiments, the heaters 135, 126 are resistance heaters. The side heater 135 and bottom heater 126 may be controlled by a control system (not shown) so that the temperature of the melt 104 is controlled throughout the pulling process.

The ingot puller apparatus 100 may include a heat shield 151. The heat shield 151 may shroud the ingot 113 and may be disposed within the crucible 102 during crystal growth (FIG. 2).

In some embodiments, the silicon substrate that is produced by the methods described herein is doped (e.g., relatively heavily doped) with boron. For example, the silicon melt may be doped with boron to produce a doped silicon ingot (or at least a segment thereof) having a boron concentration of at least 2.8×10¹⁸ atoms/cm³. Boron doping of the melt at a concentration of at least 3.8×10¹⁸ atoms/cm³ may be used to achieve an ingot with a concentration of at least 2.8×10¹⁸ atoms/cm³ at the seed end. The resulting ingot (and sliced wafers) may have a concentration of boron of at least 2.8×10¹⁸ atoms/cm³. In some embodiments, the melt is not doped with carbon (and in some embodiments no dopant other than boron is used). In some embodiments, the ingot has an oxygen concentration of less than 12 nppma.

In accordance with embodiments of the present disclosure, the (i) a growth velocity, v, and/or (ii) the axial temperature gradient, G, is controlled during the growth of at least an axial segment of the ingot such that v/G is less than a critical value of v/G. Stated differently, the growth velocity, v, and/or (ii) the axial temperature gradient, G, v/G are controlled such that A, as provided below, is negative:

Δ=(v/G)−(v/G)_{crit} (1).

Stated yet differently, the growth velocity, v, and/or (ii) the axial temperature gradient, G, are controlled such that the ratio (R) of v/G to the critical v/G, as provided below, is less than 1:

R=(v/G)/(V/G)_{crit} (2).

By controlling the ratio of v/G during silicon growth, the type of dominant defect may be controlled. At a higher v/G, the convection of the point defects dominates their diffusion, and vacancies remain the incorporated dominant point defects because the vacancy concentration at the interface is higher than the interstitial concentration. At a lower v/G, the diffusion dominates the convection, allowing the incorporation of the fast diffusing interstitials as the dominant point defect. At a v/G close to its critical value (i.e., the transition between vacancy and interstitial dominated material), both the point defects are incorporated in very low and comparable concentrations.

In accordance with embodiments of the present disclosure, (i) a growth velocity, v, and/or (ii) an axial temperature gradient, G, may be controlled during the growth of an axial segment of the constant diameter portion of the ingot such that the ratio v/G is below the critical value of v/G (e.g., across the entire radius) to cause vacancy concentrations in the ingot to be reduced or eliminated. As v/G is generally highest at the center of the ingot, in some embodiments, v/G at the center is controlled (e.g., calculated) to be below the critical value of v/G such that the entire radius of the ingot will be below the critical value of v/G.

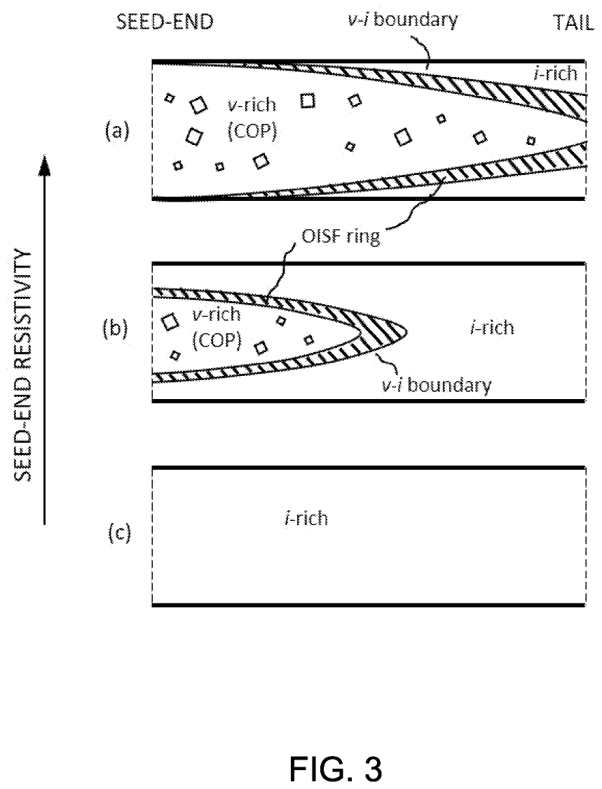

The critical v/G generally changes based on the amount of boron doping (see, e.g., Dornberger et al., “Influence of Boron Concentration on the Oxidation-induced Stacking Fault Ring in Czochralski Silicon Crystals”, Journal of Crystal Growth, 180, pp. 343-352 (1997), which is incorporated herein by reference for all relevant and consistent purposes). Boron shifts the equilibrium to the interstitial regime. With increasing boron concentration (i.e., decreasing resistivity), the vacancy-dominated region shrinks until it disappears entirely at the crystal center (FIGS. 3B-C). In this regard, the critical v/G may be determined based on a target boron concentration of the single crystal silicon ingot and with comparison with literature values of critical v/G for the given boron concentration (e.g., with reference to Dornberger et al.) and/or according to the following equation:

(v/G)_{crit}=1.34×10⁻³+1.2×10⁻²²*C_{B}(cm²/min*K) (3)

with CB being the boron concentration.

As noted above, v/G may be controlled such that interstitials are the dominant intrinsic point defect for at least a segment (e.g., axial segment) of the ingot. This segment of the ingot may have a length that is at least 0.5 times the length (D) of the constant diameter portion of the ingot (0.5*D). In other embodiments, the length of the segment is at least 0.75*D or at least 0.9*D. In some embodiments, the segment is the entire constant diameter portion of the ingot.

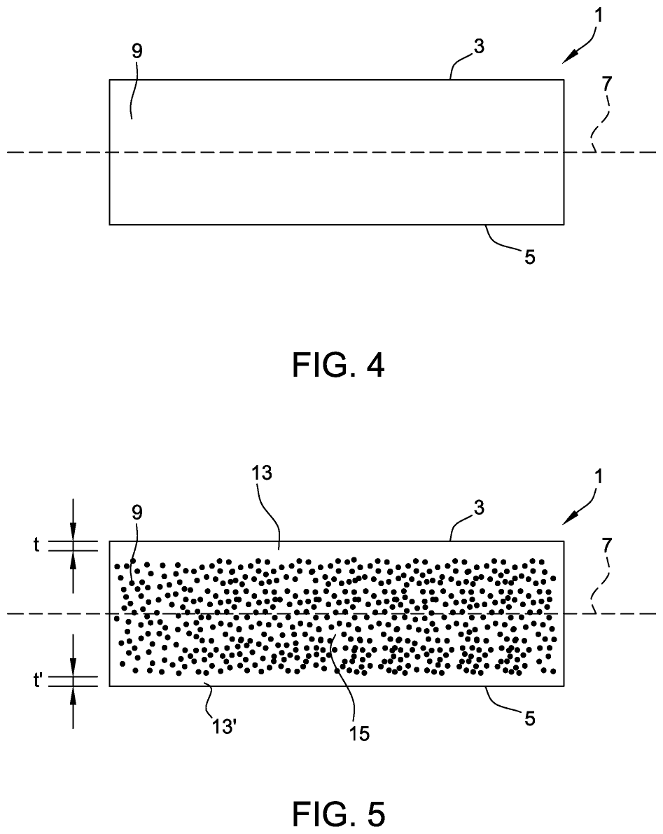

Once the ingot has been grown, the ingot is sliced into a plurality of silicon substrates (i.e., wafers). Referring now to FIG. 4, each silicon substrate 1 has a front surface 3, a back surface 5, an imaginary central plane 7 between the front and back surfaces, and a wafer bulk 9 comprising the wafer volume between the front and back surfaces.

The resulting substrates 1 have a distribution of grown-in oxygen precipitate nuclei which form during ingot cooling. Generally, in p+ ingots there is a relatively uniform grown-in precipitate density. During subsequent heat-treatments these grow-in precipitates may grow or dissolve. The stability of these precipitates is influenced by the distribution and concentration of intrinsic point defects. Without being bound by any particular theory, it is believed that vacancies enhance the stabilization and growth of oxygen precipitates (due to stresses relaxation), causing oxide particles to be more difficult to dissolve thereby reducing the denuded zone depth. When v/G is slightly above the critical value, there is a higher residual vacancy concentration (vacancies that are not efficiently consumed by voids grow due to a low initial concentration), so oxygen nuclei are more stable. Ingot growth parameters may be controlled to form a residual defect point distribution that is more suitable for formation of a denuded zone in the near surface region and formation of oxygen precipitates in the wafer bulk. Such substrates are capable of internal gettering, while having a deeper denuded zone, thereby reducing or eliminating dislocations and slip during subsequent device fabrication (e.g., upon fabricated of deep trenches).

For example and with reference to FIG. 5, after a subsequent heat-treatment (e.g., a typical customer heat-treatment) that includes a relatively high temperature step (for example above 1150° C.), the resulting depth distribution of oxygen precipitates in the wafer is characterized by clear regions of oxygen precipitate-free material (precipitate free zones or “denuded zones”) 13 and 13′ extending from the front surface 3 and back surface 5 to a depth t, t′ respectively. Stated differently, the denuded zone is a front surface layer 13 which comprises a region of the wafer 1 between the front surface 3 and a distance, D1, which is measured from the front surface 3 and toward the central plane 7. Between these oxygen precipitate-free regions 13, 13′, is a precipitation zone 15 containing a substantially uniform density of oxygen precipitates. In general, the density of precipitates will be greater than about 1×10⁸ and less than about 1×10¹¹ precipitates/cm³, with precipitate densities of about 5×10⁹ or 5×10¹⁰ per cm³ being typical in some embodiments.

The distance t, t′ (which may also be referred to herein as distance D1) from the front and back surfaces, respectively, of oxygen precipitate-free material (i.e., denuded zones 13 and 13′) is, in part, a function of the oxygen concentration, resistivity (e.g., dopant concentration), other ingot growth conditions (e.g., residual point defect concentration), and heat treatment temperature. In some embodiments, the depth t, t′ (i.e., the denuded zone depth D1) is at least about 15 μm or, as in other embodiments, at least about 20 μm, at least about 30 μm, at least about 40 μm, or at least about 50 μm (e.g., from about 15 μm to about 100 μm, from about 20 μm to about 100 μm, from about 30 μm to about 100 μm).

In this regard it is to be further noted that, in general, a denuded zone is a zone occupying the region near the surface of a wafer which has (i) an absence of oxygen precipitates in excess of the current detection limit (currently about 10⁶ oxygen precipitates/cm³) and (ii) a low concentration of, and preferably an essential absence of oxygen precipitation centers which, upon being subjected to an oxygen precipitation heat-treatment, are converted to oxygen precipitates. The presence (or density) of oxygen precipitate nucleation centers cannot be directly measured using presently available techniques. They may be indirectly measured, however, if they are stabilized and oxygen precipitates are grown at these sites by subjecting the silicon to an oxygen precipitation heat treatment. Upon being subjected to an oxygen precipitation heat-treatment at a temperature in excess of about 700° C., the denuded zone has an oxygen precipitate density of less than about 1×10⁶ cm⁻³ while the bulk layer has an oxygen precipitate density of greater than about 1×10⁶ cm⁻³. In some embodiments, upon being annealed at a temperature of 800° C. for four hours and then at a temperature of 1000° C. for sixteen hours, the denuded zone has less than about 10⁶ oxygen precipitates/cm³.

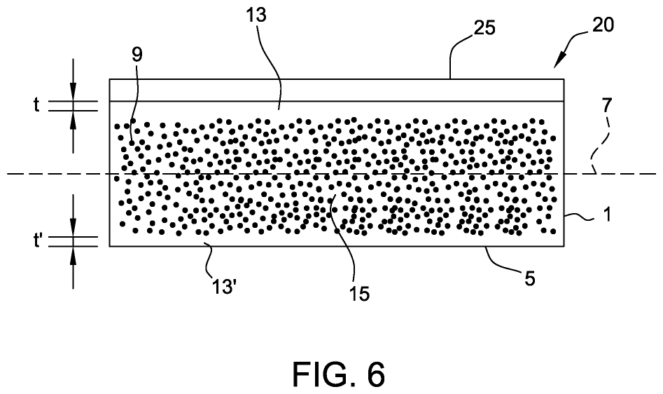

Once the wafers have been sliced from the ingot and processed (e.g., various steps of smoothing and/or reduction in surface roughness), an epitaxial layer 25 (FIG. 6) may be deposited on the front surface 3 (FIG. 5) of the substrate 1 by contacting the front surface 3 with a silicon-containing gas that decomposes and forms an epitaxial silicon layer 25 on the substrate 1. Generally, any of the methods available to those of skill in the art for depositing a silicon epitaxial layer on a silicon substrate may be used unless stated otherwise. Silicon may be deposited by epitaxy to any suitable thickness depending on the device application. For example, the silicon may be deposited using metalorganic chemical vapor deposition (MOCVD), physical vapor deposition (PVD), chemical vapor deposition (CVD), low pressure chemical vapor deposition (LPCVD), plasma enhanced chemical vapor deposition (PECVD), or molecular beam epitaxy (MBE). Silicon precursors (i.e., silicon-containing gases) for LPCVD or PECVD include methyl silane, silicon tetrahydride (silane), trisilane, disilane, pentasilane, neopentasilane, tetrasilane, dichlorosilane (SiH₂Cl₂), trichlorosilane (SiHCl₃), silicon tetrachloride (SiCl₄), among others. For example, silicon may be deposited onto the surface by pyrolyzing silane (SiH₄) in a temperature range between about 550° C. and about 690° C., such as between about 580° C. and about 650° C. The chamber pressure may range from about 70 to about 400 mTorr.

A boron-containing gas may be introduced into the epitaxial reactor to dope the epitaxial layer with boron. For example, B₂H₆ may be added to the deposition gas. The mole fraction of B₂H₆ in the atmosphere used to obtain the desired properties (e.g., resistivity) will depend on several factors, such as the amount of boron out-diffusion from the particular substrate during the epitaxial deposition, the quantity of p-type dopants and n-type dopants that are present in the reactor and substrate as contaminants, and the reactor pressure and temperature. In some embodiments, the resulting epitaxial structure (i.e., substrate and epitaxial layer) is doped with boron at concentrations sufficient to achieve a p/p+ epitaxial wafer (e.g., an epitaxial layer having a boron concentration up to 2×10¹⁶ atoms/cm³).

The resulting epitaxial wafer 20 (FIG. 6) has a relatively thick denuded zone 13 below the epitaxial layer (i.e., below the interface between the substate and the epitaxial layer) that extends toward the central plane (e.g., at least about 15 μm thick, at least about 20 μm thick, at least about 30 μm thick, at least about 40 μm thick, or at least about 50 μm thick).

Compared to other methods for forming an epitaxial wafer, the methods of the present disclosure have several advantages. Heavily doping the substrate with boron (e.g., a boron concentration of 2.8×10¹⁸ atoms/cm³ or more) has been found to suppress the formation of interstitial-type dislocation loops. Heavily doping the substrate with boron has also been found to enhance oxygen precipitation. By keeping v/G below the critical value in the relatively heavily-doped substrate, vacancies may be substantially eliminated which increases the depth of the denuded zone that forms after an oxygen precipitate heat treatment (e.g., high temperature steps above 1150° C.). Such denuded zones may form even at relatively high oxygen concentrations (e.g., up to 12 nppma).

### EXAMPLES

The processes of the present disclosure are further illustrated by the following Examples. These Examples should not be viewed in a limiting sense.

### Example 1

### Denuded Zone Depth as a Function of Δ (v/G−(v/G) crit)

Single crystal silicon ingot test crystals (200 mm) doped with boron were grown by the Czochralski method in an ingot puller similar to the ingot puller shown in FIGS. 1-2. The ingots were doped in the range of 2.7×10¹⁸ atoms/cm³ to 4.0×10¹⁸ atoms/cm³ (resistivity of 22.42 mΩ*cm to 17.2 mΩ*cm, respectively). The oxygen concentration of the single crystal silicon ingots was 10.01 to 11.8 nppma.

The crystals were grown under different process conditions, in order to explore a wide range of values of the parameter Δ (i.e., (v/G)−(v/G)_{crit}). This was achieved by varying the pull rate v in the same hot zone and by choosing a different hot zone (with a different value of the axial thermal gradient G). The crystals were sliced in wafers and were polished. An epitaxial layer was grown on the polished wafers under standard conditions. The epitaxial wafers were then submitted to a thermal cycle typical of silicon semiconductor devices production, in particular including a high temperature denuding step at 1150° C. After the thermal cycle, the denuded zone (DZ) was evaluated by a cleave and etch method.

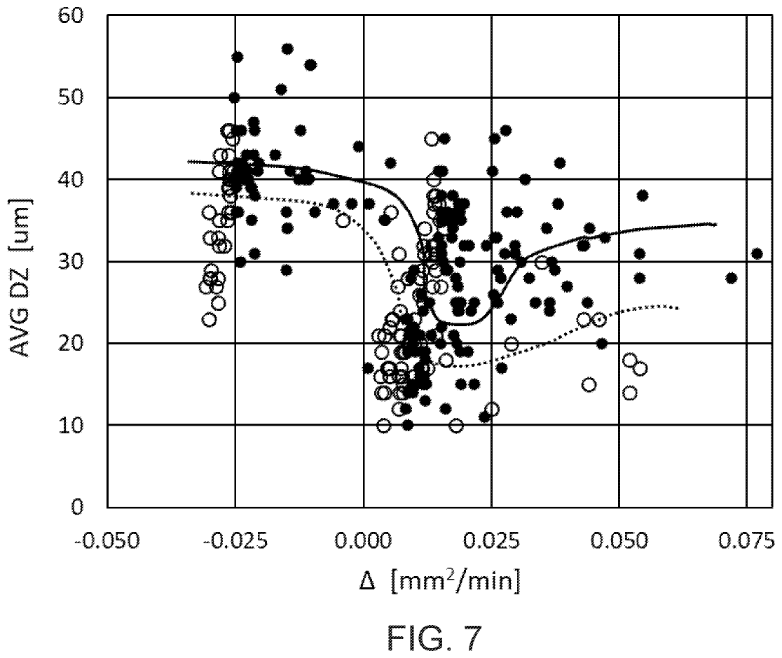

The measurement results are shown in FIG. 7 as a function of the parameter Δ (black symbols having a resistivity greater than 20 mΩ*cm and open symbols having a resistivity less than 20 mΩ*cm). For the group of samples with resistivity lower than 20 mΩcm (open symbols), the denuded zone was thickest (28-40 μm) when Δ was negative. When Δ was positive, the denuded zone was overall smaller and reached a minimum average thickness (10-12 μm) when Δ was in the vicinity of 0.02 mm²/K*min. Without being bound to any particular theory, it is believed that this value of A represents the condition for which the residual vacancy concentration (after annihilation with interstitials and consumption by voids) is maximum. A high residual vacancy concentration is believed to enhance the oxygen precipitation and, under these conditions, the denuded is more difficult to form. When Δ is very small but positive (≈0.005-0.025 mm² /K*min), the denuded zone thickness was more scattered, showing both large and narrow denuded zones. This could be due to the narrow Δ range in which the transition between the best and the worst condition for denuded zone thickness takes place. There are at least three factors that give data scattering: (i) small fluctuations of actual pull rate could give slight deviations from estimated Δ (moreover it is estimated an average Δ per ingot, not a punctual value); (ii) the thermal gradient G is calculated by FEM simulations that necessary have some simplifications limiting precision what affects v/G and Δ values; (iii) the oxygen concentration has a strong impact, even in the relatively narrow range of 10.01-11.8 nppma, with wafers with lower oxygen having larger denuded zones. To increase the denuded zone width (and less variability), a value of the parameter Δ which is relatively far from this critical value of 0.02 mm²/K*min may be chosen, and preferably a negative value of the parameter Δ is chosen.

For the group of samples with resistivity greater than 20 mΩcm (closed circles), the denuded zone thickness is overall larger compared to the previous samples (those with resistivity lower than 20 mΩ·cm), due to the lower boron concentration that favors less oxygen precipitation. This group of samples follows the same trend as a function of the parameter Δ. In this case the maximum denuded zone depth is reached when the parameter Δ is negative or zero, meaning no excess vacancy incorporation, and it reaches the minimum in correspondence of the same critical value for Δ of 0.02 mm²/K*min, confirming the conclusions derived from the first group of samples (with the variability considerations described above being applicable).

The average denuded zone depth for various ranges of Δ (i.e., (v/G)−(v/G)crit) is shown in Table 1 below.

TABLE 1
Average denuded zone depth for samples with
resistivity greater than 20 mΩ*cm and less than 20 mΩ*cm

| | Δ <= 0 | Δ~0.02 | Δ > 0.03 |
|---|---|---|---|
| Res > 20 mΩ*cm | 41.5 μm | 28.4 μm | 30.6 μm |
| Res < 20 mΩ*cm | 36 μm | 13.3 μm | 20 μm |

The same conclusions are drawn if the ratio (R) is considered. In this case, when R<1 the crystal grows in interstitial rich regime, when R>1 the crystal grows in vacancy regime. The worst condition for denuded zone depth (maximum residual vacancy concentration) appeared to be R≈1.13.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method for forming an epitaxial wafer comprising a substrate and an epitaxial layer disposed on the substrate, the method comprising:
adding an initial charge of polycrystalline silicon to a crucible;
heating the crucible comprising the initial charge of polycrystalline silicon to cause a silicon melt to form in the crucible;
adding boron to the crucible to produce a doped silicon melt;
contacting a silicon seed crystal with the doped silicon melt;
withdrawing the silicon seed crystal to grow a single crystal silicon ingot, the ingot having a constant diameter portion, the constant diameter portion of the ingot having a boron concentration of at least about 2.8×10¹⁸ atoms/cm³;
controlling (i) a growth velocity, v, and/or (ii) an axial temperature gradient, G, during the growth of a segment of the constant diameter portion of the ingot such that v/G is less than a critical v/G; and
slicing a plurality of silicon substrates from the single crystal silicon ingot; and
contacting a front surface of one of the plurality of silicon substrates with a silicon-containing gas, the silicon-containing gas decomposing to form an epitaxial silicon layer on the silicon substrate.

2. The method as set forth in claim 1 wherein the critical value of v/G changes with the boron concentration of the silicon ingot.

3. The method as set forth in claim 2 wherein the critical v/G is determined based on a target boron concentration of the single crystal silicon ingot.

4. The method as set forth in claim 1 wherein the single crystal silicon ingot has an oxygen concentration of less than 12 nppma.

5. The method as set forth in claim 1 wherein the constant diameter portion has a length D, the length of the segment being at least 0.5*D.

6. The method as set forth in claim 1 wherein the constant diameter portion has a length D, the length of the segment being at least 0.9*D.

7. The method as set forth in claim 1 wherein the length of the segment is the entire constant diameter portion of the ingot.

8. The method as set forth in claim 1 wherein the melt is not doped with carbon.

9. The method as set forth in claim 1 wherein each of the plurality of silicon substrates has a front surface, a back surface, and a central plane approximately equidistant between the front and back surfaces, each of the plurality of silicon substrates comprising:
a front surface layer which comprises a region of the wafer between the front surface and a distance, D1, which, as measured from the front surface and toward the central plane, is at least about 15 μm; and
a bulk layer which extends from the front surface layer toward the back surface.

10. The method as set forth in claim 9 wherein upon being subjected to an oxygen precipitation heat-treatment at a temperature in excess of about 700° C., the silicon substrate comprises a denuded zone in the front surface layer, the front surface layer having less than about 1×10⁶ oxygen precipitates/cm³ and the bulk layer having more than about 1×10⁶ oxygen precipitates/cm³.

11. The method as set forth in claim 9 wherein the bulk layer has more than about 1×10⁸ oxygen precipitates/cm³.

12. The method as set forth in claim 9 wherein the front surface layer has an interstitial oxygen concentration of less than 12 nppma.

13. The method as set forth in claim 9 wherein the front surface layer comprises a region of the wafer between the front surface and a distance, D1, which, as measured from the front surface and toward the central plane, is at least about 20 μm.

14. The method as set forth in claim 9 wherein the front surface layer comprises a region of the wafer between the front surface and a distance, D1, which, as measured from the front surface and toward the central plane, is at least about 50 μm.

15. The method as set forth in claim 9 wherein the front surface layer comprises a region of the wafer between the front surface and a distance, D1, which, as measured from the front surface and toward the central plane, is from about 15 μm to about 100 μm.

16. The method as set forth in claim 9 wherein the front surface layer comprises a region of the wafer between the front surface and a distance, D1, which, as measured from the front surface and toward the central plane, is from about 30 μm to about 100 μm.
